(19) United States
(12) Patent Application Publication
(10) Pub. No.: US 2013/0026589 A1
(43) Pub. Date: Jan. 31, 2013

(54) MINIATURIZATION ACTIVE SENSING MODULE AND METHOD OF MANUFACTURING THE SAME

(71) Applicants: YING-CHENG WU, TAOYUAN COUNTY (TW); KANG-WEI LEE, YILAN COUNTY (TW)

(72) Inventors: YING-CHENG WU, TAOYUAN COUNTY (TW); KANG-WEI LEE, YILAN COUNTY (TW)

(73) Assignees: LITE-ON TECHNOLOGY CORPORATION, TAIPEI CITY (TW); SILITEK ELECTRONIC (GUANGZHOU) CO., LTD., GUANGZHOU (CN)

(21) Appl. No.: 13/243,800

(22) Filed: Sep. 23, 2011

(30) Foreign Application Priority Data
Jul. 26, 2011 (CN) 201110209501.7

(51) Int. Cl. H01L 31/0232; H01L 31/18

(52) U.S. Cl. 257/432; 438/69; 257/E31.127; 257/E31.001

(57) ABSTRACT

A miniaturization active sensing module includes a substrate unit, an active sensing unit, and an optical unit. The substrate unit includes a substrate body, a plurality of first bottom conductive pads disposed on the bottom side of the substrate body, and a plurality of first conductive tracks embedded in the substrate body. The substrate body has at least one first groove formed therein. The active sensing unit includes at least one active sensing chip embedded in the first groove. The active sensing chip has at least one active sensing area and a plurality of electric conduction pads disposed on the top side thereof, and each first conductive track has two ends electrically contacted by one electric conduction pad and one first bottom conductive pad, respectively. The optical unit includes at least one optical element, disposed on the substrate body, for protecting the active sensing area.

### BACKGROUND OF THE INVENTION

1. Field of the Invention

The instant disclosure relates to an active sensing module and a method of manufacturing the same, and more particularly, to a control device and a miniaturization active sensing module and a method of manufacturing the same.

2. Description of Related Art

With a rapid progress in multimedia, digital images are extensively applied, and therefore demands for image processing devices are increasing. Currently, various digital image products including web cameras, digital cameras, optical scanners, and image phones employ image sensors, for retrieving images. The image sensor includes a CCD image sensor chip and a CMOS image sensor chip that are capable of receiving light emitted by scene and transmitting the light into digital signals. The image sensor chips require light sources for receiving, and accordingly a package method of these image sensor chips is different from a package method of normal electronic products.

The conventional package technology applied to the image sensor chips mostly includes a plastic leadless chip carrier (PLCC) technology or a ceramic leadless chip carrier (CLCC) technology. For instance, the conventional image sensor chip package structure formed by applying the CLCC technology includes a ceramic base, an image sensor chip, and a glass cover plate. The image sensor chip is disposed on the ceramic base and electrically connected with the ceramic base by wire bonding. Besides, the glass cover plate is assembled to the ceramic base, and the glass cover plate and the ceramic base together form a sealed space for accommodating the image sensor chip, such that the image sensor chip and wires are protected. On the other hand, light is able to be transmitted to the image sensor chip through the glass cover plate.

However, the conductive wires used to electrically connect the conventional image sensor chip with the ceramic base still occupy most of space in the conventional image sensor chip package structure, thus the whole thickness of the conventional image sensor chip package structure cannot be reduced.

### SUMMARY OF THE INVENTION

One aspect of the instant disclosure relates to a miniaturization active sensing module that can be applied to any electronic product having a miniaturization space.

Another aspect of the instant disclosure relates to a method of manufacturing a miniaturization active sensing module in order to reduce the whole thickness of the miniaturization active sensing module.

One of the embodiments of the instant disclosure provides a miniaturization active sensing module, comprising: a substrate unit, an active sensing unit, and an optical unit. The substrate unit includes a substrate body having a bottom side and a top side, a plurality of first bottom conductive pads disposed on the bottom side of the substrate body, and a plurality of first conductive tracks each having two ends and embedded in the substrate body, wherein the substrate body has at least one first groove formed therein and at least one second groove concaved downwardly from the top side thereof, and the at least one first groove is communicated with the at least one second groove. The active sensing unit includes at least one active sensing chip embedded in the at least one first groove, wherein the at least one active sensing chip has at least one active sensing area and a plurality of electric conduction pads, and the two ends of each first conductive track are electrically contacted by at least one of the plurality of the electric conduction pads and at least one of the plurality of the first bottom conductive pads, respectively. The optical unit includes at least one optical element, disposed in the second groove, for protecting the at least one active sensing area of the at least one active sensing chip in the at least one first groove.

Therefore, because the at least one active sensing chip can be embedded in the at least one first groove, the whole thickness of the miniaturization active sensing module can be reduced. Hence, the miniaturization active sensing module of the instant disclosure can be applied to any electronic product having a miniaturization space.

To further understand the techniques, means and effects of the instant disclosure applied for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1 shows a flowchart of the method of manufacturing the miniaturization active sensing module according to the first embodiment of the instant disclosure;

FIGS. 2A to 2K are lateral, schematic views of the miniaturization active sensing module according to the first embodiment of the instant disclosure, at different stages of the manufacturing processes, respectively;

FIG. 2L shows a lateral, schematic view of the miniaturization active sensing module according to the first embodiment of the instant disclosure;

FIG. 3 shows a lateral, schematic view of the miniaturization active sensing module according to the second embodiment of the instant disclosure;

FIG. 4 shows a lateral, schematic view of the miniaturization active sensing module according to the third embodiment of the instant disclosure; and

FIG. 5 shows a lateral, schematic view of the miniaturization active sensing module according to the fourth embodiment of the instant disclosure.

### DETAILED DESCRIPTION OF THE PREFERRED EMBODIMENTS

### First Embodiment

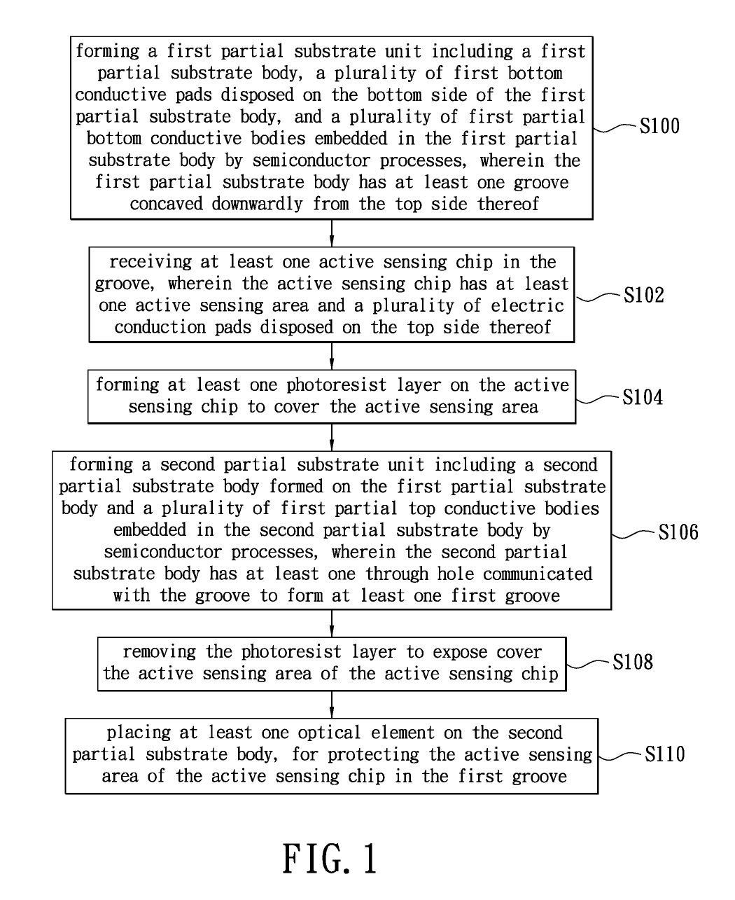

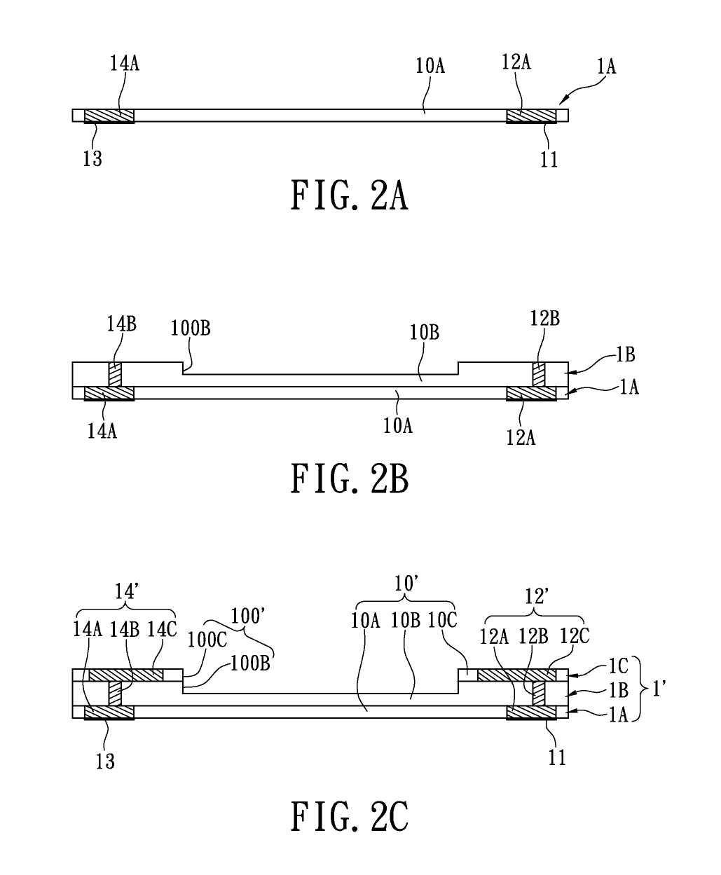

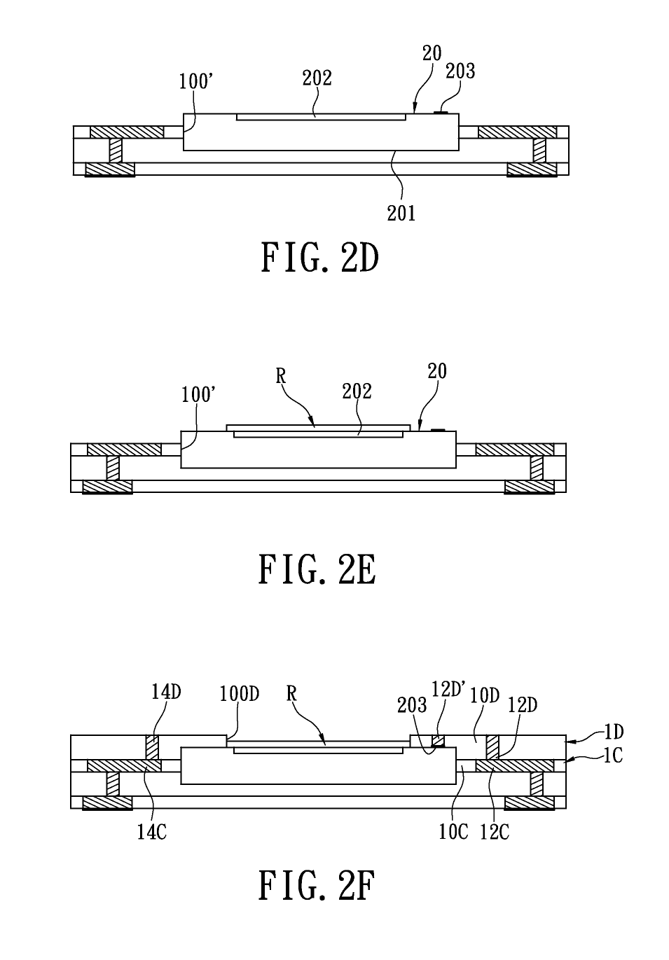

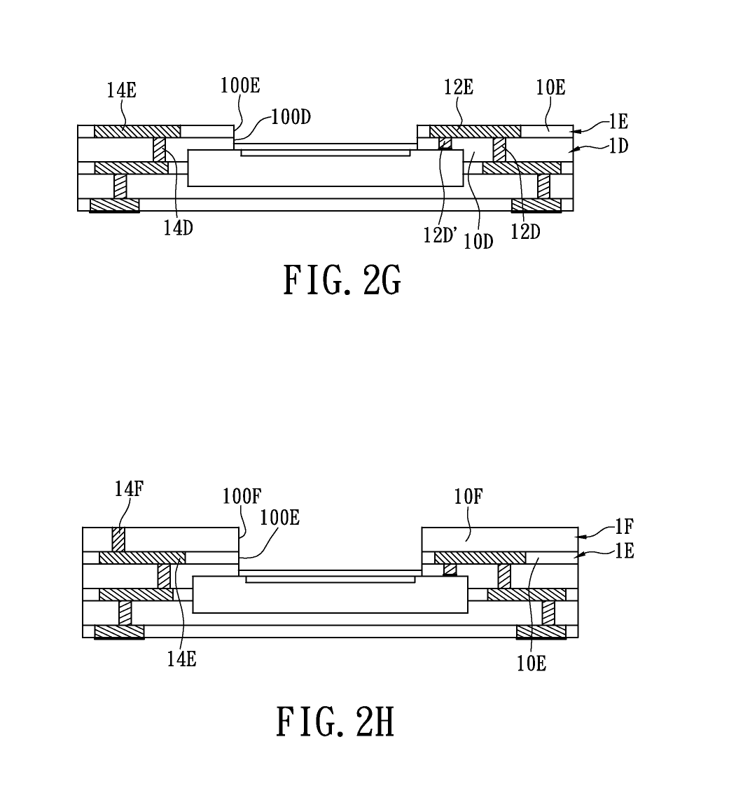

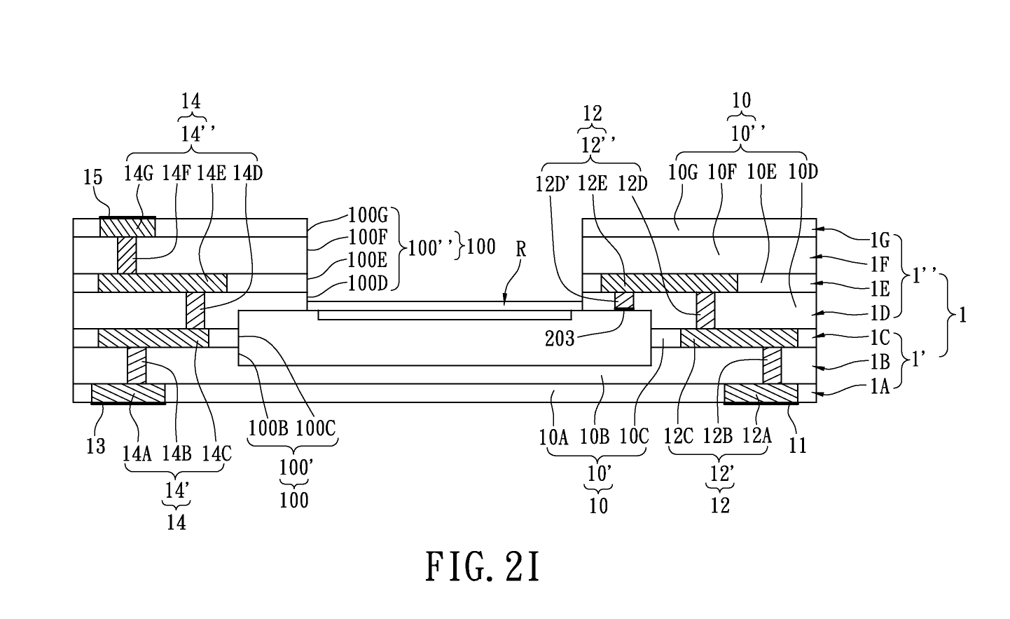

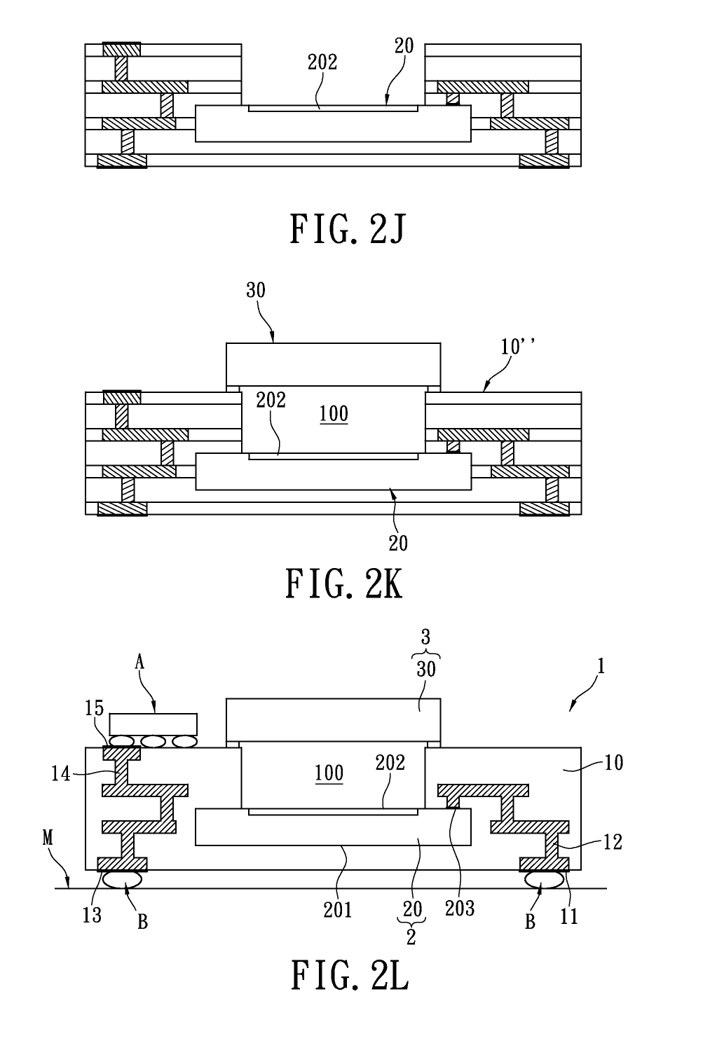

Referring to FIGS. 1 and 2A-2K, where the first embodiment of the instant disclosure provides a method of manufacturing a miniaturization active sensing module. The method comprises the steps from S100 to S110, as follows:

The step S100 is that: referring to FIGS. 1 and 2C, forming a first partial substrate unit 1′ including a first partial substrate body 10′, a plurality of first bottom conductive pads 11 disposed on the bottom side of the first partial substrate body 10′, and a plurality of first partial bottom conductive bodies 12′ embedded in the first partial substrate body 10′ by semiconductor processes, wherein the first partial substrate body 10′ has at least one groove 100′ concaved downwardly from the top side thereof Moreover, the first partial substrate unit 1′ further includes a plurality of second bottom conductive pads 13 disposed on the bottom side of the first partial substrate body 10′ and a plurality of second partial bottom conductive bodies 14′ embedded in the first partial substrate body 10′ by semiconductor processes.

For example, referring to FIGS. 2A to 2C, the step of forming the first partial substrate unit 1′ further comprises: forming a first-layer substrate unit 1A including a first-layer substrate body 10A, a plurality of first main conductive bodies 12A, and a plurality of first minor conductive bodies 14A (as shown in FIG. 2A); forming a second-layer substrate unit 1B including a second-layer substrate body 10B having at least one groove portion 100B, a plurality of second main conductive bodies 12B, and a plurality of second minor conductive bodies 14B (as shown in FIG. 2B); and then forming a third-layer substrate unit 1C including a third-layer substrate body 10C having at least one first through portion communicated with the groove portion 100B to form at least one open-type groove 100′, a plurality of third main conductive bodies 12C, and a plurality of third minor conductive bodies 14C (as shown in FIG. 2C).

The step S102 is that: referring to FIGS. 1, 2C, and 2D, receiving at least one active sensing chip 20 in the groove 100′, wherein the active sensing chip 20 has a polished surface 201 formed on the bottom side thereof, and the active sensing chip 20 has at least one active sensing area 202 for actively sensing image signals and a plurality of electric conduction pads 203 disposed on the top side thereof For example, the active sensing chip 20 is an embedded-type chip that is protected, thus the bottom portion of the active sensing chip 20 can be polished by a predetermined thickness in order to reduce the whole thickness of the active sensing chip 20.

The step S104 is that: referring to FIGS. 1 and 2E, forming at least one photoresist layer R on the active sensing chip 20 to cover the active sensing area 202. In other words, after the active sensing chip 20 is positioned in the groove 100′, the photoresist layer R formed by semiconductor processes can be used to cover the active sensing area 202. Hence, the photoresist layer R can prevent the active sensing area 202 of the active sensing chip 20 from being polluted during the following steps (after the step S104).

The step S106 is that: referring to FIGS. 1 and 21, forming a second partial substrate unit 1″ including a second partial substrate body 10″ formed on the first partial substrate body 10′ and a plurality of first partial top conductive bodies 12″ embedded in the second partial substrate body 10″ by semiconductor processes, wherein the second partial substrate body 10″ has at least one through hole 100″ communicated with the groove 100′ to form at least one first groove 100. In addition, the first partial top conductive bodies 12″ are respectively connected to the first partial bottom conductive bodies 12′ to form a plurality of first conductive tracks 12, and each first conductive track 12 has two ends electrically contacted by at least one of the plurality of the electric conduction pads 203 and at least one of the plurality of the first bottom conductive pads 11, respectively. Moreover, the second partial substrate unit 1″ further includes a plurality of top conductive pads 15 disposed on the top side of the second partial substrate body 10″ and a plurality of second partial top conductive bodies 14″ embedded in the second partial substrate body 10″ by semiconductor processes. The second partial top conductive bodies 14″ are respectively connected to the first partial bottom conductive bodies 14′ to form a plurality of second conductive tracks 14, and each second conductive track 14 has two ends respectively electrically contact at least one of the top conductive pads 15 and at least one of the second bottom conductive pads 13.

For example, referring to FIGS. 2F to 21, the step of forming the second partial substrate unit 1″ further comprises:

First, referring to FIG. 2F, forming a fourth-layer substrate unit 1D including a fourth-layer substrate body 10D formed on the third-layer substrate body 10C to cover one part of the active sensing chip 20, a plurality of fourth main conductive bodies 12D passing through the fourth-layer substrate body 10D and respectively electrically connected to the third main conductive bodies 12C, a plurality of fourth minor conductive bodies 14D passing through the fourth-layer substrate body 10D and respectively electrically connected to the third minor conductive bodies 14C, and a plurality of end conductive bodies 12D′ respectively corresponding to the fourth main conductive bodies 12D and respectively electrically contacting the plurality of the electric conduction pads 203 of the active sensing chip 20. In addition, the fourth-layer substrate body 10D has at least one second through portion 100D for exposing the photoresist layer R.

Next, referring to FIG. 2G, forming a fifth-layer substrate unit 1E including a fifth-layer substrate body 10E formed on the fourth-layer substrate body 10D, a plurality of fifth main conductive bodies 12E passing through the fifth-layer substrate body 10E, and a plurality of fifth minor conductive bodies 14E passing through the fifth-layer substrate body 10E and respectively electrically connected to the fourth minor conductive bodies 14D. In addition, each fifth main conductive body 12E is connected between one of the fourth main conductive bodies 12D and one of the end conductive bodies 12D′. The fifth-layer substrate body 10E has at least one third through portion 100E passing through the fifth-layer substrate body 10E and communicated with the second through portion 100D of the fourth-layer substrate body 10D.

Afterward, referring to FIG. 2H, forming a sixth-layer substrate unit 1F including a sixth-layer substrate body 10F formed on the fifth-layer substrate body 10E and a plurality of sixth minor conductive bodies 14F passing through the sixth-layer substrate body 10F and respectively electrically connected to the fifth minor conductive bodies 14E. In addition, the sixth-layer substrate body 10F has at least one fourth through portion 100F passing through the sixth-layer substrate body 10F and communicated with the third through portion 100E of the fifth-layer substrate body 10E.

Finally, referring to FIG. 2I, forming a seventh-layer substrate unit 1G including a seventh-layer substrate body 10G formed on the sixth-layer substrate body 10F and a plurality of seventh minor conductive bodies 14G passing through the seventh-layer substrate body 10G and respectively electrically connected to the sixth minor conductive bodies 14F. In addition, the seventh-layer substrate body 10G has at least one fifth through portion 100G passing through the seventh-layer substrate body 10G and communicated with the fourth through portion 100F of the sixth-layer substrate body 10F. In addition, the top conductive pads 15 can be respectively formed on the top sides of the seventh minor conductive bodies 14G.

The step S108 is that: referring to FIGS. 1, 2I, and 2J, removing the photoresist layer R to expose cover the active sensing area 202 of the active sensing chip 20.

The step S110 is that: referring to FIGS. 1 and 2K, placing at least one optical element 30 on the second partial substrate body 10″, for protecting the active sensing area 202 of the active sensing chip 20 in the first groove 100. In addition, the optical element 30 is positioned above the active sensing chip 20 and corresponds to the active sensing area 202 of the active sensing chip 20, and the active sensing area 202 of the active sensing chip 20 faces the optical element 30.

Referring to FIG. 2L, the first embodiment of the instant disclosure provides a miniaturization active sensing module, comprising: a substrate unit 1, an active sensing unit 2, and an optical unit 3.

Moreover, the substrate unit 1 includes a substrate body 10 having a bottom side and a top side, a plurality of first bottom conductive pads 11 disposed on the bottom side of the substrate body 10, and a plurality of first conductive tracks 12 each having two ends and embedded in the substrate body 10. The substrate body 10 has at least one first groove 100 formed therein and concaved downwardly from the top side thereof In addition, the substrate unit 1 includes a plurality of top conductive pads 15 disposed on the top side of the substrate body 10, a plurality of second bottom conductive pads 13 disposed on the bottom side of the substrate body 10, and a plurality of second conductive tracks 14 embedded in the substrate body 10, and each second conductive track 14 has two ends respectively electrically contact at least one of the top conductive pads 15 and at least one of the second bottom conductive pads 13.

Furthermore, the active sensing unit 2 includes at least one active sensing chip 20 embedded in the first groove 100. The active sensing chip 20 has a polished surface 201 formed on the bottom side thereof, and the active sensing chip 20 has at least one active sensing area 202 and a plurality of electric conduction pads 203 disposed on the top side thereof The two ends of each first conductive track 12 are electrically contacted by at least one of the plurality of the electric conduction pads 203 and at least one of the plurality of the first bottom conductive pads 11, respectively.

Besides, the optical unit 3 includes at least one optical element 30, disposed on the top side of the substrate body 10, for protecting the active sensing area 202 of the active sensing chip 20. The optical element 30 is positioned above the active sensing chip 20 and corresponds to the active sensing area 202 of the active sensing chip 20, and the active sensing area 202 of the active sensing chip 20 faces the optical element 30.

In addition, the miniaturization active sensing module of the first embodiment further comprises a plurality of active elements A (or passive elements) disposed on the top side of the substrate body 10 and selectively electrically connected to the top conductive pads 15. The miniaturization active sensing module can be electrically connected to a main printed circuit board M through a plurality of conductive solder balls B (or metal bumps).

### Second Embodiment

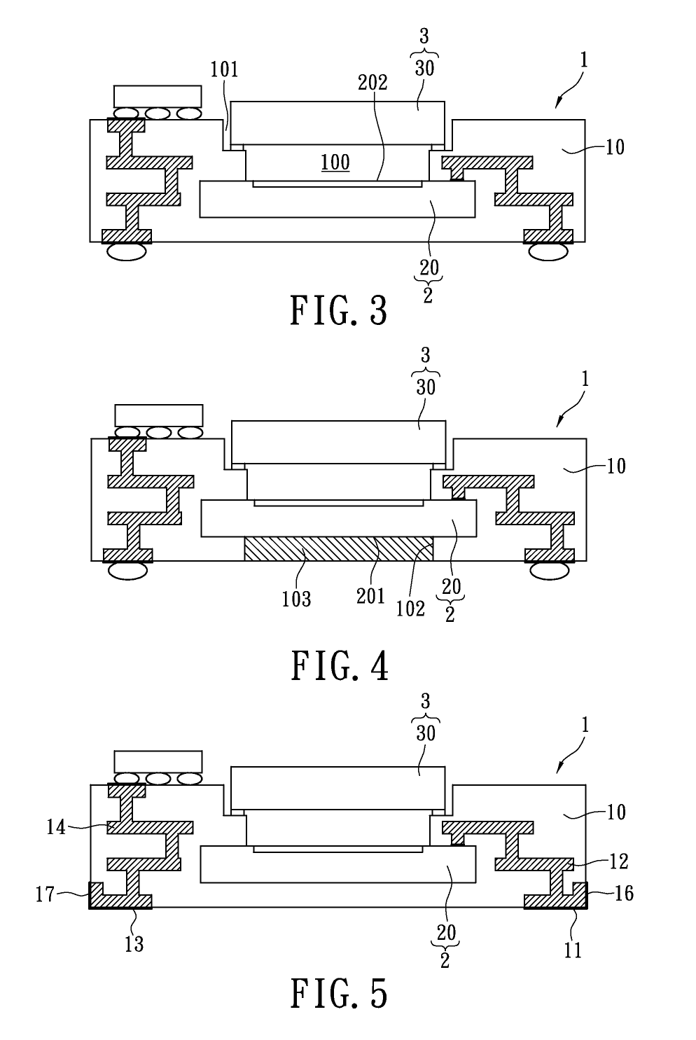

Referring to FIG. 3, where the second embodiment of the instant disclosure provides a miniaturization active sensing module. Comparing FIG. 3 with FIG. 2L, the difference between the second embodiment and the first embodiment is as follows: in the second embodiment, the substrate body 10 has at least one second groove 101 concaved downwardly from the top side thereof The second groove 101 is formed above the first groove 100 and is communicated with the first groove 100, and the optical element 30 can be positioned in the second groove 101. In other words, the second groove 101 can be concaved downwardly from the top side of the substrate body 10 and communicated with the first groove 100, thus the optical element 30 can be received in second groove 101, for protecting the active sensing area 202 of the active sensing chip 20 in the first groove 100. Hence, the optical element 30 can be fully or partially positioned in the second groove 101, for reducing the whole thickness of the miniaturization active sensing module.

### Third Embodiment

Referring to FIG. 4, where the third embodiment of the instant disclosure provides a miniaturization active sensing module. Comparing FIG. 4 with FIG. 3, the difference between the third embodiment and the second embodiment is as follows: in the third embodiment, the substrate body 10 has a through hole 102 formed under the active sensing chip 20 and a heat-dissipating body 103, and the through hole 102 passes through the substrate body 10 and is filled with the heat-dissipating body 103. The heat-dissipating body 103 can contact the polished surface 201 of the active sensing chip 20, thus heat generated by the active sensing chip 20 can be transmitted to the external environment through the heat-dissipating body 103 in order to increase the heat-dissipating efficiency of the miniaturization active sensing module.

### Fourth Embodiment

Referring to FIG. 5, where the fourth embodiment of the instant disclosure provides a miniaturization active sensing module. Comparing FIG. 5 with FIG. 4, the difference between the fourth embodiment and the third embodiment is as follows: in the fourth embodiment, the substrate unit 10 includes a plurality of first lateral conductive pads 16 disposed on the lateral side thereof, and the first lateral conductive pads 16 respectively contact the first conductive tracks 12 and respectively (electrically) connected to the plurality of the first bottom conductive pads 11. Moreover, the substrate unit 10 includes a plurality of second lateral conductive pads 17 disposed on the lateral side thereof, and the second lateral conductive pads 17 respectively contact the second conductive tracks 14 and respectively connected to the second bottom conductive pads 13. In other words, the fourth embodiment can selectively use the plurality of the first bottom conductive pads 11 and the second bottom conductive pads 13 to supply power to the active sensing chip 20 or use the first lateral conductive pads 16 and the second lateral conductive pads 17 to supply power to the active sensing chip 20.

In conclusion, because the active sensing chip can be embedded in the first groove, the whole thickness of the miniaturization active sensing module can be reduced. Hence, the miniaturization active sensing module of the instant disclosure can be applied to any electronic product having a miniaturization space.

The above-mentioned descriptions merely represent the preferred embodiments of the instant disclosure, without any intention or ability to limit the scope of the instant disclosure which is fully described only within the following claims Various equivalent changes, alterations or modifications based on the claims of instant disclosure are all, consequently, viewed as being embraced by the scope of the instant disclosure.

What is claimed is:

1. A miniaturization active sensing module, comprising:
a substrate unit including a substrate body having a bottom side and a top side, a plurality of first bottom conductive pads disposed on the bottom side of the substrate body, and a plurality of first conductive tracks each having two ends and embedded in the substrate body, wherein the substrate body has at least one first groove formed therein and at least one second groove concaved downwardly from the top side thereof, and the at least one first groove is communicated with the at least one second groove;
an active sensing unit including at least one active sensing chip embedded in the at least one first groove, wherein the at least one active sensing chip has at least one active sensing area and a plurality of electric conduction pads, and the two ends of each first conductive track are electrically contacted by at least one of the plurality of the electric conduction pads and at least one of the plurality of the first bottom conductive pads, respectively; and
an optical unit including at least one optical element, disposed in the second groove, for protecting the at least one active sensing area of the at least one active sensing chip in the at least one first groove.

2. The miniaturization active sensing module of claim 1, wherein the substrate body has a through hole formed under the at least one active sensing chip and a heat-dissipating body, the through hole passes through the substrate body and is filled with the heat-dissipating body, and the at least one active sensing chip has a polished surface formed on the bottom side thereof to contact the heat-dissipating body.

3. The miniaturization active sensing module of claim 1, wherein the substrate unit includes a plurality of first lateral conductive pads disposed on the lateral side thereof, and the first lateral conductive pads respectively contact the first conductive tracks and respectively connected to the plurality of the first bottom conductive pads.

4. The miniaturization active sensing module of claim 1, wherein the substrate unit includes a plurality of top conductive pads disposed on the top side of the substrate body, a plurality of second bottom conductive pads disposed on the bottom side of the substrate body, and a plurality of second conductive tracks embedded in the substrate body, and each second conductive track has two ends respectively electrically contact at least one of the top conductive pads and at least one of the second bottom conductive pads.

5. The miniaturization active sensing module of claim 4, wherein the substrate unit includes a plurality of second lateral conductive pads disposed on the lateral side thereof, and the second lateral conductive pads respectively contact the second conductive tracks and respectively connected to the second bottom conductive pads.

6. The miniaturization active sensing module of claim 1, wherein the at least one active sensing area of the at least one active sensing chip faces the at least one optical element.

7. A miniaturization active sensing module, comprising:
a substrate unit including a substrate body having a bottom side and a top side, a plurality of first bottom conductive pads disposed on the bottom side of the substrate body, and a plurality of first conductive tracks each having two ends and embedded in the substrate body, wherein the substrate body has at least one first groove formed therein;
an active sensing unit including at least one active sensing chip embedded in the at least one first groove, wherein the at least one active sensing chip has at least one active sensing area and a plurality of electric conduction pads, and the two ends of each first conductive track are electrically contacted by at least one of the plurality of the electric conduction pads and at least one of the plurality of the first bottom conductive pads, respectively; and
a photoresist unit including at least one photoresist layer disposed on the at least one active sensing chip to cover the at least one active sensing area.

8. The miniaturization active sensing module of claim 7, wherein the substrate body has a through hole formed under the at least one active sensing chip and a heat-dissipating body, the through hole passes through the substrate body and is filled with the heat-dissipating body, and the at least one active sensing chip has a polished surface formed on the bottom side thereof to contact the heat-dissipating body.

9. A method of manufacturing a miniaturization active sensing module, comprising the steps of:
forming a first partial substrate unit, wherein the first partial substrate unit includes a first partial substrate body, a plurality of first bottom conductive pads disposed on the bottom side of the first partial substrate body, and a plurality of first partial bottom conductive bodies embedded in the first partial substrate body by semiconductor processes, and the first partial substrate body has at least one groove;
receiving at least one active sensing chip in the at least one groove, wherein the at least one active sensing chip has at least one active sensing area and a plurality of electric conduction pads disposed on the top side thereof;
forming at least one photoresist layer on the at least one active sensing chip to cover the at least one active sensing area;
forming a second partial substrate unit, wherein the second partial substrate unit includes a second partial substrate body formed on the first partial substrate body and a plurality of first partial top conductive bodies embedded in the second partial substrate body by semiconductor processes, the second partial substrate body has at least one through hole communicated with the at least one groove to form at least one first groove, the first partial top conductive bodies are respectively connected to the first partial bottom conductive bodies to form a plurality of first conductive tracks, and each first conductive track has two ends electrically contacted by at least one of the plurality of the electric conduction pads and at least one of the plurality of the first bottom conductive pads, respectively;
removing the at least one photoresist layer to expose cover the at least one active sensing area; and
placing at least one optical element on the second partial substrate body, for protecting the at least one active sensing area of the at least one active sensing chip in the at least one first groove.
